(19) United States
(12) Patent Application Publication
(10) Pub. No.: US 2026/0059877 A1
(43) Pub. Date: Feb. 26, 2026

(54) IMAGE SENSOR

(71) Applicant: SAMSUNG ELECTRONICS CO., LTD., Suwon-si (KR)

(72) Inventors: Sooyoung KANG, Suwon-si (KR); Minsung KIM, Suwon-si (KR); Sungin KIM, Suwon-si (KR); Dongmo IM, Suwon-si (KR)

(73) Assignee: SAMSUNG ELECTRONICS CO., LTD., Suwon-si (KR)

(21) Appl. No.: 19/278,400

(22) Filed: Jul. 23, 2025

(30) Foreign Application Priority Data
Aug. 22, 2024 (KR) 10-2024-0112848

(51) Int. Cl. H10F 39/00; H10F 39/18

(52) U.S. Cl. CPC H10F 39/80373; H10F 39/014; H10F 39/182; H10F 39/807; H10F 39/811

(57) ABSTRACT

An image sensor includes a semiconductor substrate having a first surface and a second surface provided opposite to each other, a photoelectric conversion region in the semiconductor substrate, a device isolation pattern provided on the first surface of the semiconductor substrate and defining an active region, a floating diffusion region provided adjacent to the first surface of the semiconductor substrate, and a vertical transfer gate embedded in the semiconductor substrate from the first surface of the semiconductor substrate and provided adjacent to the floating diffusion region. The vertical transfer gate includes a first vertical electrode and a second vertical electrode extending in a vertical direction in the semiconductor substrate, and an electrode pad embedded in the semiconductor substrate from the first surface of the semiconductor substrate and connecting the first and second vertical electrodes.

### CROSS-REFERENCE TO RELATED APPLICATION(S)

This application is based on and claims the benefit under 35 USC 119(a) of Korean Patent Application No. 10-2024-0112848 filed on Aug. 22, 2024 in the Korean Intellectual Property Office, the entire disclosure of which is incorporated herein by reference for all purposes.

### BACKGROUND

The disclosure relates to an image sensor.

An image sensor is a device converting an optical image signal into an electrical signal. An image sensor has a plurality of pixels, and each pixel includes a photoelectric conversion region (for example, a photodiode) receiving incident light and converts the light into an electrical signal, and a pixel circuit using charges generated in the diode region to output a pixel signal. As the integration of the image sensor increases, the size of each pixel decreases and the sizes of respective components of the pixel circuit also decrease, and thus, there is a problem in which leakage current or the like through the pixel circuit occurs, deteriorating the quality of the image sensor.

### SUMMARY

Example embodiments provide an image sensor having improved electrical characteristics such as reduced parasitic capacitance.

According to an aspect of the disclosure, there is provided an image sensor including: a semiconductor substrate having a first surface and a second surface; a photoelectric conversion region in the semiconductor substrate; a device isolation pattern provided on the first surface of the semiconductor substrate and defining an active region; a floating diffusion region provided adjacent to the first surface of the semiconductor substrate; and a vertical transfer gate extending from the first surface of the semiconductor substrate towards the second surface of the semiconductor substrate and provided adjacent to the floating diffusion region, wherein the vertical transfer gate includes: a first vertical electrode and a second vertical electrode, each of the first vertical electrode and the second vertical electrode extending in a vertical direction into the semiconductor substrate; and an electrode pad embedded in the semiconductor substrate and connecting the first vertical electrode and the second vertical electrode.

According to an aspect of the disclosure, there is provided an image sensor including: a semiconductor substrate having a first surface and a second surface; a first photoelectric conversion region and a second photoelectric conversion region provided adjacent to each other in the semiconductor substrate; a first floating diffusion region and a second floating diffusion region provided adjacent to the first surface of the semiconductor substrate and overlapping the first and second photoelectric conversion regions in a vertical direction that is perpendicular to the first surface, respectively; and a first vertical transfer gate and a second vertical transfer gate extending from the first surface of the semiconductor substrate toward the second surface of the semiconductor substrate, the first vertical transfer gate and the second vertical transfer gate and provided adjacent to the first and second floating diffusion regions, respectively, wherein the first vertical transfer gate includes: a plurality of first vertical electrodes each extending in the vertical direction in the semiconductor substrate, and a first electrode pad embedded in the semiconductor substrate and connecting the plurality of first vertical electrodes, and wherein the second vertical transfer gate includes: a plurality of second vertical electrodes each extending in the vertical direction in the semiconductor substrate, and a second electrode pad embedded in the semiconductor substrate and connecting the plurality of second vertical electrodes.

According to an aspect of the disclosure, there is provided an image sensor including: a semiconductor substrate having a first surface and a second surface; a photoelectric conversion region in the semiconductor substrate; a device isolation pattern provided on the first surface of the semiconductor substrate and defining an active region; a floating diffusion region provided adjacent to the first surface of the semiconductor substrate; a vertical transfer gate extending from the first surface of the semiconductor substrate towards the second surface of the semiconductor substrate and provided adjacent to the floating diffusion region; and a buried gate electrode embedded in the active region from the first surface of the semiconductor substrate to a first depth, wherein the vertical transfer gate includes: a first vertical electrode and a second vertical electrode extending to a second depth greater than the first depth, in a vertical direction in the semiconductor substrate, and an electrode pad embedded in the semiconductor substrate from the first surface of the semiconductor substrate to the second depth and connecting the first and second vertical electrodes.

### BRIEF DESCRIPTION OF DRAWINGS

The above and other aspects, features, and advantages of the embodiments of the disclosure will be more clearly understood from the following detailed description, taken in conjunction with the accompanying drawings, in which:

FIG. 1 is an exploded perspective view illustrating an image sensor according to an example embodiment;

FIG. 2 is a plan view of part “A” of the image sensor of FIG. 1 according to an example embodiment;

FIG. 3 is a cross-sectional view taken along line I-I′ in the portion of the image sensor illustrated in FIG. 2 according to an example embodiment;

FIG. 4 is a plan view illustrating a pixel array corresponding to part “B” in the portion of the image sensor illustrated in FIG. 2 according to an example embodiment;

FIG. 5 is a circuit diagram of a unit pixel of the pixel array of FIG. 4;

FIG. 6A and FIG. 6B are partial cross-sectional views taken along line I1-I1′ and line II1-II1′ of the pixel array of FIG. 4, respectively;

FIG. 7 is a plan view illustrating a pixel array of an image sensor according to an example embodiment;

FIG. 8 is a partial cross-sectional view taken along line II2-II2′ of the pixel array of FIG. 7;

FIGS. 9A to 9E are process cross-sectional views illustrating a method of manufacturing an image sensor (dual vertical transfer gate forming process) according to an example embodiment;

FIGS. 10A and 10B are process plan views corresponding to FIGS. 9A and 9B, respectively; and

FIG. 11 is a plan view illustrating a pixel array (4×4) of an image sensor according to an example embodiment.

### DETAILED DESCRIPTION

Hereinafter, various embodiments will be described in detail with reference to the accompanying drawings.

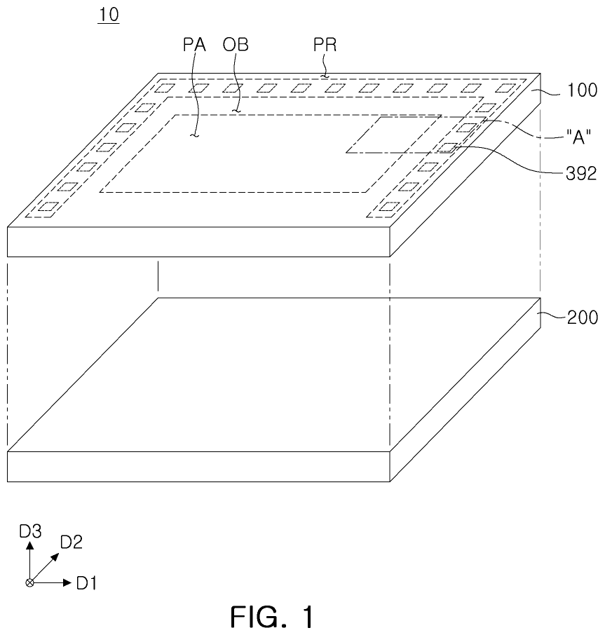

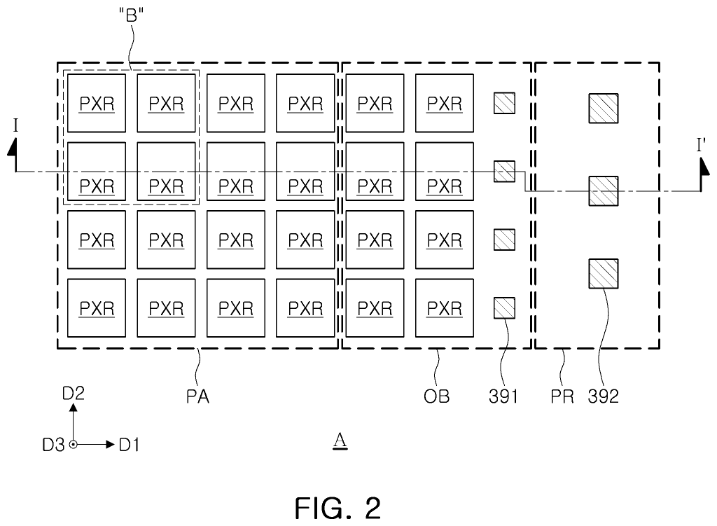

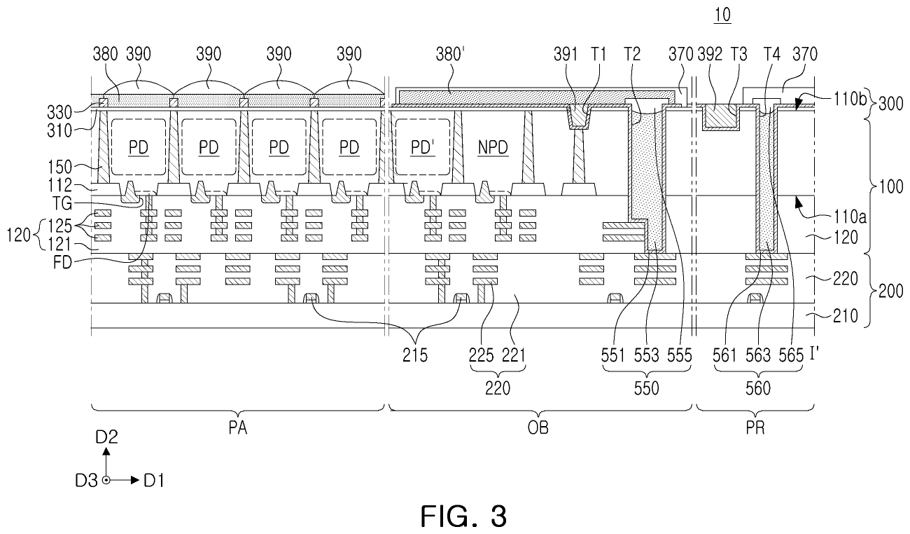

FIG. 1 is an exploded perspective view illustrating an image sensor according to an example embodiment, FIG. 2 is a plan view of a portion “A” of the image sensor of FIG. 1, and FIG. 3 is a cross-sectional view taken along line I-I′ of the portion of the image sensor illustrated in FIG. 2.

Referring to FIGS. 1 to 3, the image sensor 300 according to the embodiment may include a first substrate structure 100 and a second substrate structure 200. The first substrate structure 100 and the second substrate structure 200 maybe laminated and electrically connected to each other. The first substrate structure 100 may include a first substrate 110 having a pixel array area (PA), a first interconnection structure 120 on a first surface 110a of the first substrate 110, and a light-transmitting structure 300 on a second surface 110b of the substrate 110. The second substrate structure 200 may include a second substrate 210 having a first surface on which logic devices 215 are provided, and a second interconnection structure 220 that contacts the first interconnection structure 120 on the second substrate 210. The first surface of the second substrate 210 may be referred to an upper surface the second substrate 210. According to an embodiment, the first substrate structure 100 may also be referred to as a ‘sensor chip’, and the second substrate structure 200 may also be referred to as a ‘logic chip’. However, the disclosure is not limited thereto.

The first substrate 110 may include a light-shielding area (OB) and a pad region (PR) in addition to a pixel array area (AR) in a planar view. The pixel array area (PA) may include a plurality of pixel regions (PXR) that receive light and generate an active signal. The plurality of pixel regions (PXR) may be arranged in a plurality of rows and a plurality of columns in the pixel array area (AR).

The light-shielding area (OB) may be provided, for example, around the pixel array area (PA). The light shielding area (OB) may include optical black pixels that block light to generate an optical black signal. In some embodiments, dummy pixels may be provided in the light shielding area (OB).

The pad region (PR) may be provided around the light shielding area (OB). In some embodiments, the pad region (PR) may be provided adjacent to the edge of the image sensor 10. For example, the pad region (PR) may be formed in a peripheral region of the image sensor 10. For example, the peripheral region may be an outer area of the image sensor near the edges of the image sensor. In the embodiment, the pad region (PR) is illustrated as being provided along three sides of the image sensor 10, but the disclosure is not limited thereto, and as such, in some embodiments, the pad region (PR) may be provided to surround two sides or the entire side (e.g., all the sides). The pad region (PR) includes a plurality of pads 390 for connection to an external device, and may be configured to transmit and receive electrical signals between the image sensor 10 and the external device.

For example, referring to FIG. 3, the first substrate 110 provided in the embodiment may include a device isolation pattern 112 defining an active region (ACT) on a first surface 110a, and pixel circuit devices such as a vertical transfer gate (TG) on the active region (ACT). A plurality of photoelectric conversion regions (PDs) may be provided in the substrate 110.

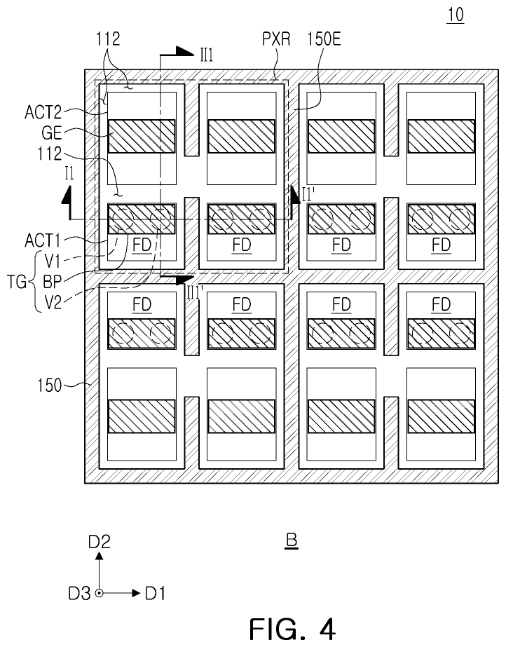

The image sensor 10 according to the embodiment may be a back-side illumination (BSI) image sensor. The second surface 110b of the first substrate 110 may be provided as a light-receiving surface on which light is incident. The first substrate 110 may further include a pixel separation pattern 150 defining a plurality of pixel regions (PXR). The pixel separation pattern 150 may be provided to surround the photoelectric conversion regions (PD). As illustrated in FIG. 4, the pixel separation pattern 150 may be provided in a grid shape to separate a plurality of pixel regions (PXR) in a planar view. The pixel separation pattern 150 may penetrate at least a portion of the first substrate 110.

The first substrate 110 may be a semiconductor substrate. For example, the first substrate 110 may be a bulk silicon or a silicon-on-insulator (SOI) substrate. As described above, a plurality of pixel regions (PXR) may be arranged planarly (for example, in a matrix) within the pixel array area (PA) along the first direction (X) and the second direction (Y). In each pixel region, at least one photoelectric conversion region (PD) may be provided in the first substrate 110. The photoelectric conversion regions (PD) may generate charges proportional to the amount of light incident from the outside. For example, the photoelectric conversion regions (PD) may be a photo diode, a photo transistor, a photo gate, a pinned photo diode, or an organic photo diode.

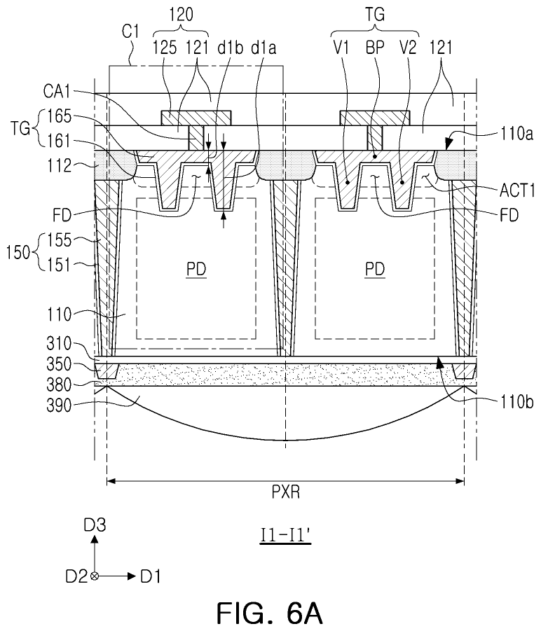

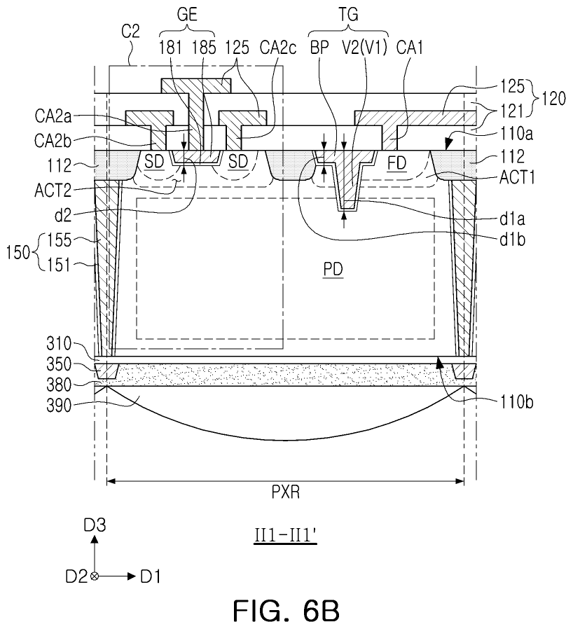

As described above, the first substrate 110 may include pixel circuit devices formed in the active region (ACT) of the first surface 110a of the first substrate 110. The pixel circuit devices may include a transfer gate (TG) and various circuit devices. The circuit devices may each include a gate GE (as shown in FIG. 6B) and a source/drain SD (as shown in FIG. 6B). The pixel circuit devices will be described in detail with reference to FIGS. 4, 5, 6A, and 6B.

The photoelectric conversion regions (PD) are provided within the pixel array area (PA) provided as an active pixel, but some of the photoelectric conversion regions may be provided in the light-shielding area (OB). The photoelectric conversion region provided in the light-shielding area (OB) may be provided with a first reference region (PD′) configured identically to the photoelectric conversion regions (PD) and a second reference region (dummy photoelectric conversion region (NPD)) that does not constitute a photoelectric conversion region. In the light-shielding area (OB), the first and second reference regions (PD′ and NPD) may be provided in the first substrate 110 and may be separated by a pixel separation pattern 150.

The first interconnection structure 120 may include a first inter-wiring insulating layer 121 and a plurality of first interconnection layers 125 on the first inter-wiring insulating layer 121. The number of layers and arrangements of the interconnection layers constituting the first interconnection structure 120 illustrated in the drawing are merely illustrative. The plurality of first interconnection layers 125 may include interconnection patterns on different levels and contact vias electrically connecting the interconnection patterns and pixel circuit devices (see FIGS. 6A and 6B). The first inter-wiring insulating layer 121 may include at least one of, for example, silicon oxide, silicon nitride, silicon oxynitride, and a low-κ material having a lower dielectric constant than silicon oxide. The first interconnection layers 125 may include at least one of, for example, tungsten (W), copper (Cu), aluminum (Al), gold (Au), silver (Ag), and alloys thereof. However, the disclosure is not limited thereto, and as, the first interconnection layers 125 may include another material.

The second substrate 210 may be a bulk silicon or a silicon-on-insulator (SOI) substrate, similar to the first substrate 110. Logic circuit devices 215 may be provided on the second substrate 210. For example, the logic circuit devices 215 may include transistors that constitute a component, which may include, but not limited to, a control register block, a timing generator, a ramp signal generator, a row driver, a readout circuit, or a buffer.

In the second substrate structure 200, the second interconnection structure 220 may be provided on the second substrate 210. For example, the second interconnection structure 220 may be provided between the first interconnection structure 120 of the first substrate structure 100 and the second substrate 210.

The second interconnection structure 220 may include a second inter-wiring insulating layer 221 and a plurality of second interconnection layers 225 on the second inter-wiring insulating layer 221. The number of layers and arrangements of the interconnection layers constituting the second interconnection structure 220 illustrated in the drawing are merely illustrative. The plurality of second interconnections 225 may include interconnection patterns on different levels and vias electrically connecting the interconnection patterns and the logic devices 215. The second inter-wiring insulating layer 221 may include at least one of, for example, silicon oxide, silicon nitride, silicon oxynitride, and a low-κ material having a lower dielectric constant than silicon oxide. The second interconnection layers 225 may include at least one of, for example, tungsten (W), copper (Cu), aluminum (Al), gold (Au), silver (Ag), and alloys thereof. However, the disclosure is not limited thereto, and as, the second interconnection layers 225 may include another material.

In this embodiment, the first interconnection structure 120 may be bonded to the second interconnection structure 220. In some embodiments, the bonding insulating layer may be included at the interface of the first interconnection structure 120 and the second interconnection structure 220. The bonding insulating layer may include at least one of silicon oxide, silicon nitride, silicon oxynitride, and silicon carbonitride (SiCN), but is not limited thereto. The second interconnection structure 220 may be bonded to the first interconnection structure 120, and at the same time, the first interconnection layer 115 and the second interconnection layer 225 may be in contact with each other. For example, the first and second interconnection structures may include first and second metal pads at the bonding interface, respectively, and the first and second metal pads may be metal bonded so that the first and second interconnection layers may be electrically connected to each other.

As illustrated in FIG. 3, in the pixel array area (PA), the first substrate structure 100 may include a surface insulating layer 310 on the second surface 110b of the first substrate 110, a grid pattern 330 on the surface insulating layer 310, a color filter layer 380 covering the surface insulating layer 310 and the grid pattern 330, and micro lenses 390 on the color filter layer 380.

The surface insulating layer 310 may include an insulating material. For example, the surface insulating layer 310 may include, but is not limited to, at least one of silicon oxide, silicon nitride, silicon oxynitride, aluminum oxide, hafnium oxide, and combinations thereof. In some embodiments, the surface insulating layer 310 may be a multilayer. The surface insulating layer 310 may include an anti-reflection film. The antireflection film may improve the light receiving efficiency of the photoelectric conversion layer (PD) by preventing the reflection of light incident on the first substrate 110. In addition, the surface insulating layer 310 may include a planarizing film. The color filter layer 380 and the micro lens layer 390 described below may be formed with a uniform height. For example, the surface insulating layer 310 may include an aluminum oxide film, a hafnium oxide film, a silicon oxide film, a silicon nitride film, and a hafnium oxide film, which are sequentially laminated on the second surface 110b of the first substrate 110.

The color filter layer 380 may be provided on the surface insulating layer 310. The color filter layer 380 may be arranged to correspond to each unit pixel of the pixel array area (PA). The color filter layer 380 may have various color filters depending on the unit pixel. For example, the color filter layer 380 may include a red color filter, a green color filter, and a blue color filter. In some embodiments, the color filter layer 380 may be arranged in a Bayer pattern. However, this is merely illustrative, and the color filter layer 380 may include a yellow filter, a magenta filter, and a cyan filter, and may further include a white filter.

According to an embodiment, a grid pattern 330 may be provided between the color filters 160. The grid pattern 330 may be provided on the surface insulating layer 310. The grid pattern 330 may be interposed between the color filter layers 380. In some embodiments, the grid pattern 330 may be provided to overlap the pixel separation pattern 150 in the vertical direction d3.

In some embodiments, the grid pattern 330 may include a conductive pattern and a low refractive index pattern. The conductive pattern may effectively prevent ESD (electrostatic discharge) failure by preventing charges generated by ESD, etc. from accumulating on the surface of the first substrate 110. The low refractive index pattern may improve the light collection efficiency by refracting or reflecting light incident obliquely, thereby improving the quality of the image sensor. For example, the conductive pattern may include, but is not limited to, at least one of titanium (Ti), titanium nitride (TiN), tantalum (Ta), tantalum nitride (TaN), tungsten (W), aluminum (Al), and copper (Cu), and the low refractive index pattern may include a low refractive index material having a lower refractive index than silicon (Si). For example, the low refractive index pattern may include, but is not limited to, at least one of silicon oxide, aluminum oxide, tantalum oxide, and combinations thereof.

The micro lens layer 390 may be provided on the color filter layer 380. The micro lens layer 390 may include micro lenses arranged to correspond to each unit pixel of the pixel array area (PA). Each of the micro lenses may have a convex shape and a predetermined radius of curvature. Accordingly, the micro lenses may focus light incident on the photoelectric conversion regions (PD). The micro lens layer 390 may include, for example, a light-transmitting resin. In some embodiments, the micro lens layer 390 may extend to a portion of the peripheral area (for example, the light-shielding area (OB)).

In addition, referring to FIG. 3, the surface insulating layer 310 may extend to the light-shielding area (OB) and the pad region (PR), and may further include a first conductive layer 551 on the extended surface insulating layer 310, a light-shielding filter layer 380′ on the first conductive layer 551, and a protective layer 370 covering the light-shielding filter layer 380′. In some embodiments, the light-shielding filter layer 380′ may extend from the first conductive layer 551 to the light-shielding area (OB) and may be provided as a light-shielding structure that blocks light together with the first conductive layer 551. The light-shielding filter layer 380′ may be formed together with the color filter layer 380 and may have substantially the same thickness as the color filter layer 380, but is not limited thereto. The light-shielding filter layer 380′ may include a blue color filter or a black filter.

In some embodiments, the light-shielding area (OB) may be used to remove noise signals due to dark current. For example, in a state where light is blocked by the first conductive layer 551 and the light-shielding filter layer 380′, the first reference area (PD′) including the photodiode may be used as a reference pixel for noise removal by the photodiode. In addition, in a state where light is blocked by the first conductive layer 551 and the light-shielding filter layer 380′, the second reference area (NPD) not including the photodiode may be a region for checking process noise for noise removal by other components, not the photodiode.

A first connection structure 550 and a first contact pad 391 may be provided on a light-shielding area (OB). The first connection structure 550 may include a first conductive layer 551, a first separation pattern 553, and a first capping pattern 555. The first conductive layer 551 may cover a surface insulating layer 310 on a second surface 110b of the first substrate 110. In addition, the first conductive layer 551 may conformally cover an inner wall of the first trench T1. The first conductive layer 551 may penetrate the first substrate 110 and the first interconnection structure 120, for example, the first substrate structure 100, to connect the first interconnection layer 125 and the second interconnection layer 225 to each other. In addition, the first conductive layer 551 may be connected to the pixel separation pattern 150. The first conductive layer 551 may include a metal material. For example, the conductive layer 551 may include, but is not limited to tungsten. As described above, the first conductive layer 551 may block light incident into the light-shielding area (OB).

The first contact pad 391 may fill the first trench T1. The first contact pad 391 may include a metal material. For example, the first contact pad 391 may include, but is not limited to aluminum. The first contact pad 391 may be connected to the pixel separation pattern 150. A bias may be applied to the filling portion 155 of the pixel separation pattern 150 through the first contact pad 391.

The second connection structure 560 and the second contact pad 392 may be provided on the pad region (PR). The second connection structure 560 may include the second conductive layer 561, the second separation pattern 563, and the second capping pattern 565. The second conductive layer 561 may cover the surface insulating layer 310 on the second surface 110b of the first substrate 110. The second conductive layer 561 may conformally cover the inner wall of the second trench TR2. The second conductive layer 561 may penetrate the first substrate 110 and the first interconnection structure 120, for example, the first substrate structure 100, to connect the first interconnection layer 125 and the second interconnection layer 225 to each other. The second conductive layer 561 may include a metal material. For example, the second conductive layer 561 may include, but is not limited to tungsten. The second conductive layer 561 may block light incident into the pad region (PR).

The second contact pad 392 may fill the second trench (T2. The second contact pad 390 may include a metal material. For example, the second contact pad 390 may include, but is not limited to aluminum. The second contact pad 392 may serve as an electrical connection passage between the image sensor 10 and an external device. The second contact pad 390 may be connected to the logic devices 215 of the second substrate 210 through the second conductive layer 561 and the second interconnection layer 225. The electrical signal generated from the photoelectric conversion regions (PD) within the plurality of pixel regions (PXR) of the pixel array area (PA) may be transmitted to an external device through the first interconnection layer 125, the second interconnection layer 225, the second conductive layer 561, and the second contact pad 392.

FIG. 4 is a plan view illustrating a pixel array corresponding to the “B” portion of the image sensor in FIG. 2.

Referring to FIG. 4, a plurality of 2×2 pixel regions (PXR) arranged two-dimensionally are illustrated. The plurality of pixel regions (PXR) may be arranged along a first direction D1 and a second direction D2 parallel to the first surface 110a of the first substrate 100. The pixel separation pattern 150 may penetrate the first substrate 110 and be provided between the plurality of pixel regions (PXR). The pixel separation pattern 150 may surround each of the plurality of pixel regions (PXR) in a planar view. The pixel separation pattern 150 may prevent cross-talk between neighboring pixel regions (PXR). The pixel separation pattern 150 may extend to surround each of pixel regions (PXR) along the first direction D1 and the second direction D2. In the embodiment, the pixel separation pattern 150 may include extensions 150E extending into each of pixel regions (PXR) along the second direction D2. The first extensions 150E provided to face each other may be spaced apart from each other in the second direction D2 within each of pixel regions (PXR). On both sides of each of the pixel regions (PXR), a first photoelectric conversion region and a second photoelectric conversion region are separated and provided by the extensions. The first photoelectric conversion region and the second photoelectric conversion region may be adjacent to each other in the first direction D1 within each of pixel regions (PXR).

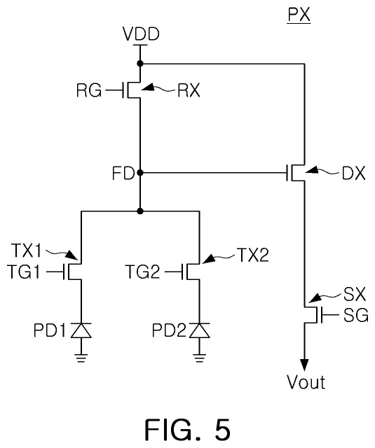

FIG. 5 is a circuit diagram of a unit pixel (PX) corresponding to each of the pixel regions (PXR) of FIG. 3.

With reference to FIG. 5, together with FIG. 3, each unit pixel (PX) may include pixel circuit devices, along with a first photoelectric conversion region PD1 and a second photoelectric conversion region PD2 respectively located on both sides of the pixel region (PXR). The pixel circuit devices may include a first transfer transistor TX1, a second transfer transistor PX2, and logic transistors (RX, SX and DX). The logic transistors (RX, SX and DX) may include a reset transistor (RX), a select transistor (SX), and a drive transistor (DX). The first transfer transistor TX1, the second transfer transistor TX2, the reset transistor (RX), and the selection transistor (SX) may each include a first transfer gate TG1, a second transfer gate TG2, a reset gate (RG), and a selection gate (SG). The first transfer transistor TX1 and the second transfer transistor PX2 may be provided on both sides of each pixel region (PXR), respectively.

The first and second photoelectric conversion regions PD1 and PD2 may generate and accumulate photocharges in proportion to the amount of light incident from the outside. The unit pixel (PX) may further include a floating diffusion region (FD). In the embodiment, the floating diffusion region (FD) may be divided into two regions and may be respectively provided on opposite sides of the pixel region (PXR) as illustrated in FIG. 4. The two floating diffusion regions (FD) may be connected to each other by the first interconnection layer 125 of FIG. 3. The first transfer transistor TX1 may transfer charges generated in the first photoelectric conversion region PD1 to the floating diffusion region (FD), and the second transfer transistor TX2 may transfer charges generated in the second photoelectric conversion region PD2 to the floating diffusion region (FD).

The floating diffusion region (FD) may receive and accumulate charges generated in the first and second photoelectric conversion regions PD1 and PD2. The drive transistor (DX) may be controlled according to the amount of photocharges accumulated in the floating diffusion region (FD). The reset transistor (RX) may periodically reset charges accumulated in the floating diffusion region (FD). The drain electrode of the reset transistor (RX) may be connected to the floating diffusion region (FD), and the source electrode of the reset transistor (RX) may be connected to the power supply voltage (VDD). In an example case in which the reset transistor (RX) is turned on, the power voltage (VDD) connected to the source electrode of the reset transistor (RX) may be applied to the floating diffusion region (FD). Therefore, in an example case in which the reset transistor (RX) is turned on, the charges accumulated in the floating diffusion region (FD) are discharged, and the floating diffusion region (FD) may be reset.

The drive transistor (DX) may act as a source follower buffer amplifier. The drive transistor (DX) may amplify the potential change in the floating diffusion region (FD) and output the amplified potential to the output line (Vout).

The selection transistor (SX) may select the pixel (PX) to be read in units of rows. In an example case in which the selection transistor (SX) is turned on, the power voltage (VDD) may be applied to the drain electrode of the drive transistor (DX). Although FIG. 4 illustrates a unit pixel region (PXR) having two photoelectric conversion regions PD1 AND PD2 and five transistors (TX1, TX2, RX, DX and SX), the image sensor according to the disclosure is not limited thereto. In an example embodiment, the reset transistor (RX), the drive transistor (DX), or the selection transistor (SX) may be shared by neighboring pixel regions (PXR). Accordingly, the integration of the image sensor may be improved.

The first and second transfer gates TG1 and TG2 provided in the embodiment may be implemented as buried vertical transfer gates having a plurality of vertical electrodes. Additionally, gates of other transistors constituting the pixel circuit may also have similar buried gates. These buried vertical gates (TG) and buried gates (GE) are described with reference to FIGS. 6A and 6B.

FIGS. 6A and 6B are partial cross-sectional views of the pixel array of FIG. 4 cut along lines I1-I1′ and II1-II1′, respectively.

Referring to FIGS. 6A and 6B, the image sensor 10 according to the embodiment may include a first substrate 110, a first interconnection structure 120, and a light-transmitting structure 300, as described above.

As described above, the pixel separation pattern 150 may be provided to surround the pixel region and may be formed to penetrate at least a portion of the first substrate 110. In the embodiment, the pixel separation pattern 150 may include a deep trench extending from the first surface 110a to the second surface 110b. The pixel separation pattern 150 may include a separation insulating layer 151 on the inner wall of the trench, and a filling portion 155 that fills the separation insulating layer 151. For example, the separation insulating layer 151 may include silicon oxide, silicon nitride, and/or silicon oxynitride, and the filling portion 155 may include a semiconductor material or a conductive material. In some embodiments, the filling portion 155 may include boron-doped polycrystalline silicon.

The device isolation pattern 112 may define an active region ACT1 and ACT2. In the embodiment, the device isolation pattern 112 may define first and second active regions ACT1 and ACT2. For example, the device isolation pattern 112 may include silicon oxide. The pixel separation pattern 130 may be connected to the device isolation pattern 112. According to an embodiment, an device isolation pattern 112 may be provided on a pixel separation pattern 130.

As illustrated in FIGS. 6A and 6B, a vertical transfer gate (TG), a floating diffusion region (FD), and a buried gate electrode (GE) for other pixel circuit devices (also called ‘logic transistors’) may be provided adjacent to a first surface 110a of a first substrate 110.

Referring to FIGS. 6A and 6B, the vertical transfer gate (TG) and the floating diffusion region (FD) may be provided in a first active region ACT1. The vertical transfer gate (TG) and the floating diffusion region (FD) may be provided on the photoelectric conversion region (PD). For example, the vertical transfer gate (TG) and the floating diffusion region (FD) may be provided to overlap with the photoelectric conversion region (PD) in a direction perpendicular to the direction (for example, D3). The floating diffusion region (FD) may be provided adjacent to the first surface 110a of the first substrate 110. The vertical transfer gate (TG) may be provided adjacent to the floating diffusion region (FD).

In the embodiment, the vertical transfer gate (TG) and the floating diffusion region (FD) may be arranged in the second direction D2. In some embodiments, the floating diffusion region (FD) may be regions doped with impurities of a different conductivity type (for example, N-type impurities) from the conductivity type (for example, P-type) of the first substrate 110. However, the disclosure is not limited thereto, and as such, the floating diffusion region (FD) may be regions doped with P-type impurities and the first substrate 110 may be N-type.

The vertical transfer gate (TG) provided in the embodiment is configured to be buried in the first substrate 110 from the first surface 110a of the first substrate 110. Referring to FIG. 6A, the vertical transfer gate (TG) may include a first vertical electrode V1 and a second vertical electrode V2, and an electrode pad (BP) connecting the first and second vertical electrodes V1 and V2. The first vertical electrode V1 and the second vertical electrode V2 may respectively extend in a vertical direction (for example, D3) in the first substrate 110 and may be connected to each of photoelectric conversion regions (PD).

In this manner, each of the first and second vertical electrodes V1 and V2 may be formed with a depth (d1a) connected to the photoelectric conversion region (PD) from the first surface 110a of the substrate 110.

In some embodiments, the first vertical electrode V1 and the second vertical electrode V2 may respectively extend vertically toward the photoelectric conversion region (PD), but may not be directly connected to the photoelectric conversion region (PD), but may overlap or be slightly spaced from the photoelectric conversion region (PD). For example, the first vertical electrode V1 and the second vertical electrode V2 may be electrically connected through another impurity region adjacent to the photoelectric conversion region (PD).

According to an embodiment, the electrode pad (BP) may be embedded in the first substrate 110 from the first surface 110a of the first substrate 110. The upper surface of the electrode pad (BP) may have the same or lower level as the first surface 110a of the first substrate 110. The electrode pad (BP) may be formed with a depth (d1b) smaller than the depth (d1a) of the first and second vertical electrodes V1 and V2. That is, a thickness of the electrode pad (BP) in the depth direction (D3) is lower than a thickness of the first and second vertical electrodes V1 and V2 in the depth direction (D3).

According to an embodiment, the first and second vertical electrodes V1 and V2 and the electrode pad (BP) are formed by the same process, and thus may have an integrated structure. The vertical transfer gate (TG) may include a first gate electrode portion 165 and a first gate insulating layer 161 between the first gate electrode portion 165 and the first substrate 110. For example, the first gate electrode portion 165 may include polycrystalline silicon, and the first gate insulating layer 161 may include silicon oxide, silicon nitride, or a ferroelectric material.

The device isolation pattern 112 has a portion provided around the vertical transfer gate (TG), and the width of the electrode pad (BP) may be defined by the device isolation pattern 112. For example, as illustrated in FIG. 6A, the width of the electrode pad (BP) in the first direction (for example, D1) may be defined by the device isolation pattern 112.

Referring to FIG. 6B, the image sensor 10 according to the embodiment may include a buried gate electrode (GE) located in a second active region ACT2 from a first surface 110a of a first substrate 110, and a pair of source/drain regions (SD) located in the second active region (ACT) between both sides of the buried gate electrode (GE) and the device isolation pattern 112. The buried gate electrode (GE) may, together with the source/drain regions (SD), form at least one or more logic transistors RX, SX and DX on the first surface 110a of the first substrate 110. The at least one or more logic transistors RX, SX and DX may include a reset transistor (RX), a selection transistor (SX), and a drive transistor (DX).

The buried gate electrode (GE) and the source/drain regions (SD) may overlap in a direction perpendicular to the photoelectric conversion region (PD) (for example, D3). In some embodiments, the source/drain regions (SD) may be regions doped with a second conductive type impurity (for example, N-type impurity) different from the conductive type (for example, P-type) of the first substrate 110.

In the embodiment, the buried gate electrode (GE) may be buried in the first substrate 110 from the first surface 110a of the first substrate 110. The upper surface of the buried gate electrode (GE) may have a level equal to or lower than the first surface 110a of the first substrate 110.

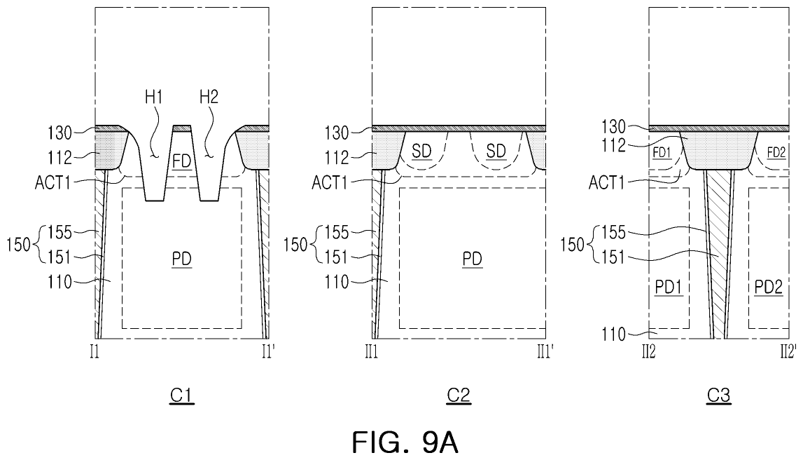

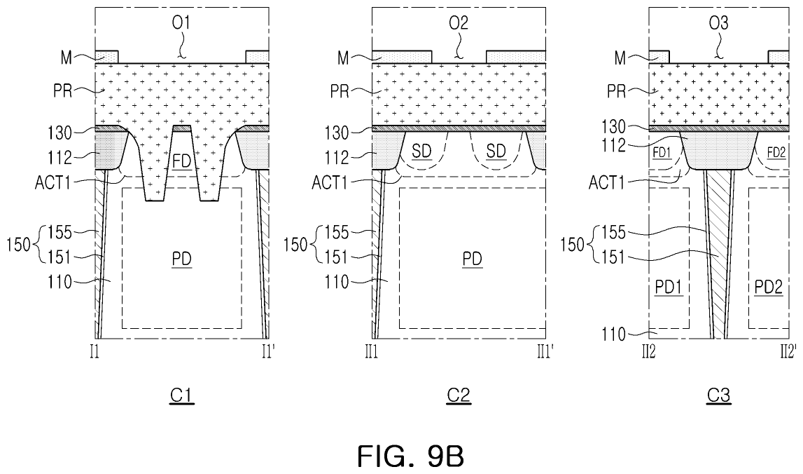

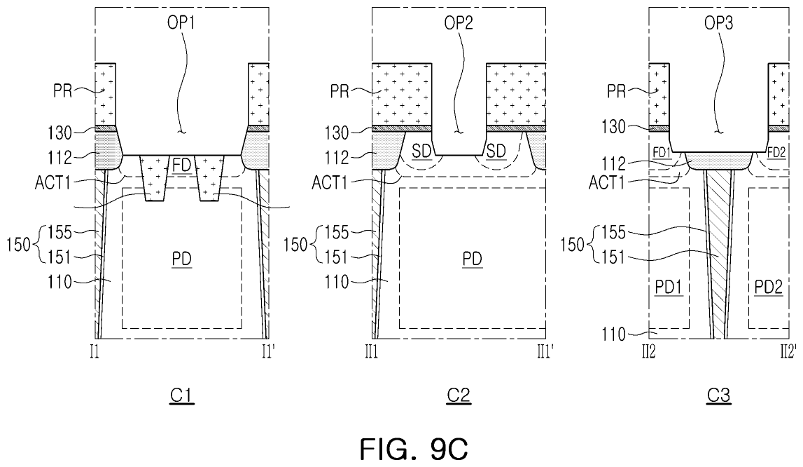

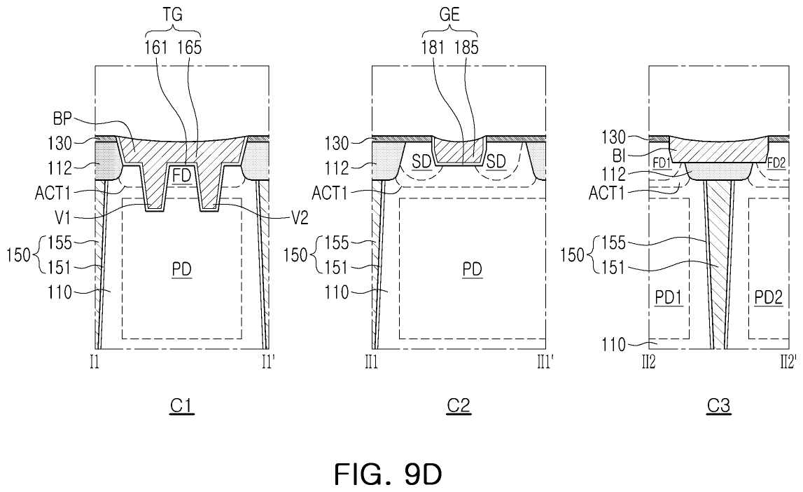

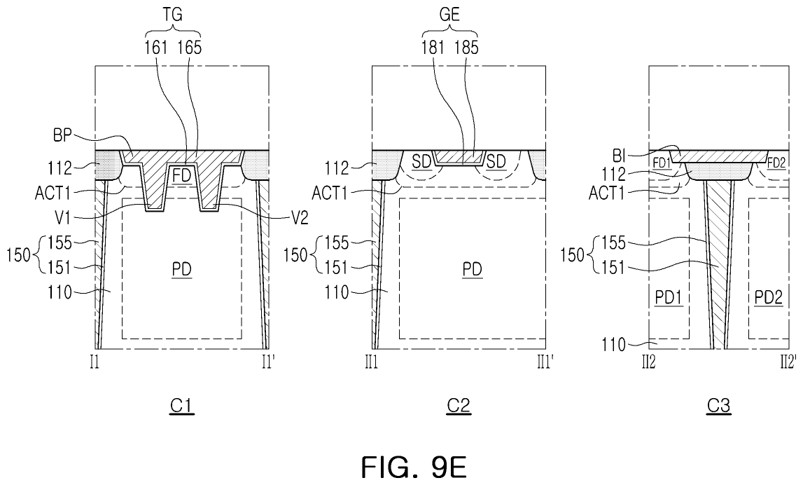

Similar to the vertical transfer gate (TG), the buried gate electrode (GE) may include a second gate electrode portion 185 and a second gate insulating layer 181 between the second gate electrode portion 185 and the first substrate 110. The buried gate electrode (GE) may be formed by the same process as the vertical transfer gate (TG) (see FIGS. 9A to 9E). The buried gate electrode (GE) may include the same material as the vertical transfer gate (TG). For example, the second gate electrode portion 185 may include polycrystalline silicon, and the second gate insulating layer 161 may include silicon oxide, silicon nitride, or a ferroelectric material.

In the embodiment, the buried gate electrode (GE) is formed at a depth d2 from the first surface 110a of the first substrate 110, and the depth d2 of the buried gate electrode (GE) may be substantially the same as the depth (d1b) of the electrode pad (BP).

Although the image sensor illustrated in FIG. 4 is exemplified as having only two buried gate electrodes (GE) in each of the pixel regions (PXR), the above-described buried gate electrodes (GE) may all be introduced as gate electrodes for the reset transistor (RX), the selection transistor (SX), and the drive transistor (DX). In some embodiments, the gate electrodes of all logic transistors provided on the first surface 110a of the first substrate 110 may be formed as buried gate electrodes (GE) together with the buried vertical transfer gate (TG) according to the embodiment.

The first interconnection structure 120 is provided on the first surface 110a of the first substrate 110 and may cover the vertical transfer gate (TG) and the buried gate electrodes (GE). The first interconnection structure 120 may include a first inter-wiring insulating layer 121 and a first interconnection layer 125 on the first inter-wiring insulating layer 121.

As illustrated in FIG. 6A, the vertical transfer gate (TG) may be electrically connected to the first interconnection layer 125 of the first interconnection structure 120. The first interconnection layer 125 may include a first contact via CA1 connected to the electrode pad (BP). In the embodiment, since the two vertical electrodes V1 and V2 are connected by one electrode pad (BP), the vertical transfer gate (TG) may be connected to the first interconnection layer 125 by one first contact via CA1.

Similarly, the first interconnection layer 125 may be connected to the buried gate electrodes (GE), floating diffusion regions (FD), and source/drain regions (SD) through other contact vias.

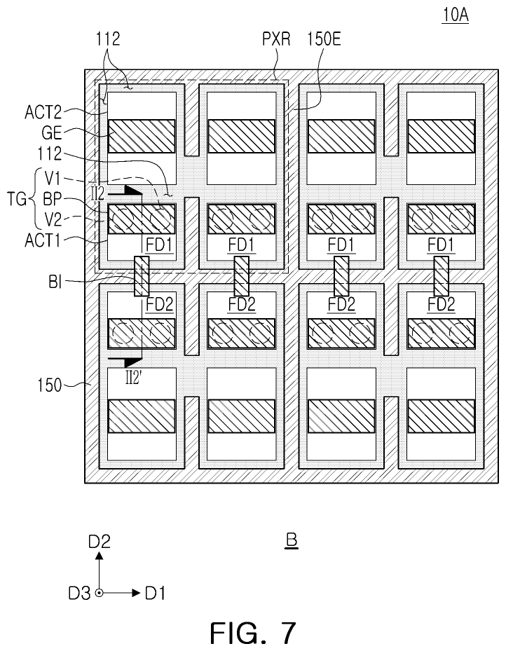

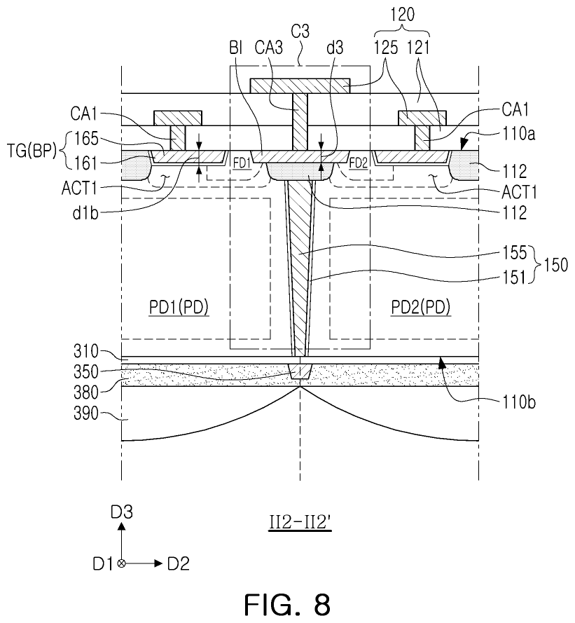

FIG. 7 is a plan view illustrating a pixel array of an image sensor according to an example embodiment, and FIG. 8 is a partial cross-sectional view taken along line II2-II2′ of the pixel array of FIG. 7.

Referring to FIGS. 7 and 8, it can be understood that the image sensor 10A according to the embodiment has a structure similar to the image sensor 10 illustrated in FIGS. 1 to 6B, except that the image sensor has a buried interconnection portion connecting adjacent first and second floating diffusion regions. In addition, the components of the embodiment may be understood by referring to the description of the same or similar components of the image sensor 10 illustrated in FIGS. 1 to 6B, unless otherwise specifically described.

The image sensor 10A according to the embodiment may have a pixel array similar to the image sensor 10 illustrated according to an embodiment in FIG. 4. Referring to FIG. 7, the first photoelectric conversion region PD1 and the second photoelectric conversion region PD2 may be provided adjacent to each other in the second direction (for example, D2).

The vertical transfer gates provided in the embodiment have a structure embedded in the first substrate from the first surface of the first substrate, similar to the previous embodiments. The vertical transfer gate (TG) may include a first vertical electrode V1 and a second vertical electrode V2, and an electrode pad (BP) connecting the first and second vertical electrodes V1 and V2. The first vertical electrode V1 and the second vertical electrode V2 may respectively extend in a vertical direction (for example, D3) in the first substrate 110 and may be connected to the first or second photoelectric conversion region PD1 or PD2, respectively.

Referring to FIG. 7, the first floating diffusion region (FD1 and the second floating diffusion region (FD2 may be arranged adjacently in the second direction (for example, D2). The image sensor 10A according to the embodiment may further include a buried interconnection (BI) connecting the adjacent first and second floating diffusion regions (FD1 and FD2) to each other. The buried interconnection (BI) may be buried in the first substrate 110 from the first surface 110a of the first substrate 110 to a predetermined depth d3. The upper surface of the buried interconnection (BI) may have a level that is the same as or lower than the first surface 110a of the first substrate 110.

In some embodiments, the buried interconnection (BI) may have a depth d3 that is the same as or similar to the depth (d1b) of the electrode pad (BP) of the vertical transfer gate (TG). The device isolation pattern 112 extends between the first and second floating diffusion regions FD1 and FD2, and may thus be provided below the buried interconnect (BI).

In this manner, since the material etched in the process of forming the buried interconnect (BI) may be different from the material etched in the process of forming the vertical transfer gate (TG) (see FIG. 9B), the depths of the two etching regions may have somewhat different differences. However, depending on the etching process applied, the depths d1b, d3 of the two etching regions may be almost the same.

Each of the vertical transfer gates (TG) may include a first gate electrode portion 165 and a first gate insulating layer 161 between the first gate electrode portion 165 and the first substrate 110. On the other hand, the buried interconnect (BI) may include the same material as the material of the first gate electrode portion 165 without the gate insulating layer. For example, the buried interconnect (BI) may include doped polycrystalline silicon.

In addition, the image sensor 10A according to the embodiment may include a buried gate electrode (GE) located in the second active region ACT2 from the first surface 110a of the first substrate 110, and a pair of source/drain regions (SD) located in the second active region (ACT) between both sides of the buried gate electrode (GE) and the device isolation pattern 112. In the embodiment, the buried gate electrode (GE) may be buried in the first substrate 110 from the first surface 110a of the first substrate 110. The upper surface of the buried gate electrode (GE) may have the same or lower level than the first surface 110a of the first substrate 110.

FIGS. 9A to 9E are process cross-sectional views illustrating a method of manufacturing an image sensor (dual vertical transfer gate forming process) according to an example embodiment. In this case, FIGS. 9A to 9E may be respectively understood as a process for portion of “C1”of FIG. 6A, “C2”of FIG. 6B, and “C3”of FIG. 8.

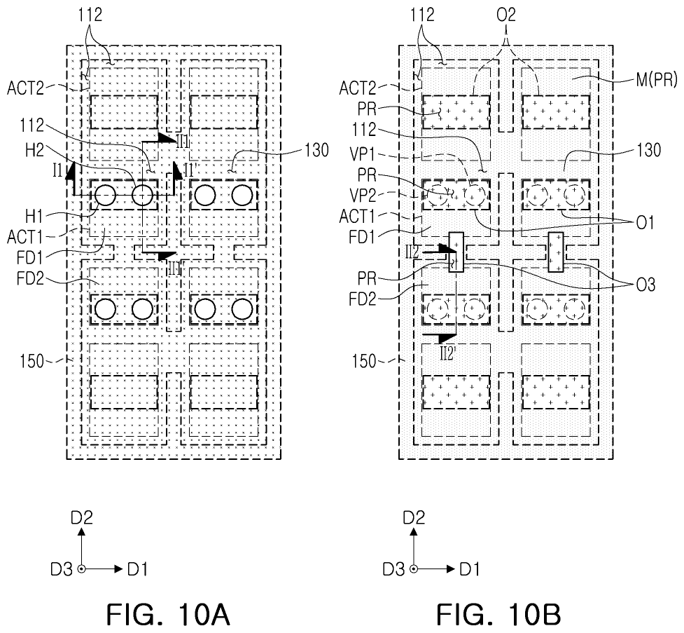

In addition, FIGS. 10A and 10B are process plan views corresponding to FIGS. 9A and 9B, respectively. In this case, FIGS. 10A and 10B may be understood as representing two pixel regions (PXR) adjacent to the second direction (for example, D2) in the plan views of FIGS. 5 and 7.

Referring to FIGS. 9A and 10A, a first hole (H1 and a second hole (H2 extending to a photoelectric conversion region (PD) may be formed on a first surface of a first substrate 110 for an image sensor.

The first substrate 101 has pixel separation patterns 150 defining a pixel region and a device isolation pattern 112 defining an active region (ACT), and additionally, a floating diffusion region (FD) and impurity regions for a source/drain region (SD) for a logic transistor may be formed in the active region (ACT). A protective layer 130 may be formed on the first surface 110a of the first substrate 110. For example, the protective layer 130 may be an insulating material such as silicon oxynitride or silicon nitride.

First and second holes H1 and H2 corresponding to the first and second vertical vias, respectively, are formed in an area where a vertical transfer gate is to be formed (see C1, for example, an area adjacent to the floating diffusion region (FD). This process may be performed by an etching process using a mask pattern (not illustrated). The first and second holes H1 and H2 may be formed to have a depth extending to the photoelectric conversion region (PD).

Next, referring to FIGS. 9B and 10B, a sacrificial material layer (PR) may be formed on the first surface 110a of the first substrate 110 so that the first and second holes H1 and H2 are filled, and a mask pattern (M) having first to third openings may be formed. The sacrificial material layer (PR) may include an oxide layer or a photoresist material. As illustrated in FIG. 10b, the first opening O1 may define an electrode pad (BP of FIG. 9D) of a vertical transfer gate, the second opening O2 may define a buried gate electrode (GE of FIG. 9D) for logic transistors, and the third opening O3 may define a buried interconnect (BI of FIG. 9D) connecting adjacent floating diffusion regions FD1 and FD2.

Next, referring to FIG. 9C, an anisotropic etching process may be performed using a mask pattern (M). A portion of the device isolation pattern 112 and a portion of the first substrate 110 may also be etched, together with portions of the sacrificial material layer (PR) respectively exposed from the first to third openings O1, O2 and O3. As a result, first to third recesses OP1, OP2 and OP3 for the electrode pad of the vertical transfer gate, the buried gate electrode, and the buried interconnection may be provided. In this manner, the first to third recesses OP1, OP2 and OP3 may be formed together by the same process.

Depending on the material to be etched during the formation process of the first to third recesses OP1, OP2 and OP3, the recess depths may have some differences, but when selecting etching conditions with low selectivity for each material, the depths of the first to third recesses OP1, OP2 and OP3 may be almost the same.

Next, referring to FIG. 9D, after removing the sacrificial material layer (PR), a conductive material may be formed so that the first to third recesses OP1, OP2 and OP3 are filled, and then a planarization process may be performed.

In the process of removing the remaining sacrificial material layer (PR), the sacrificial material layer portions VP1 and VP2 filled in the first and second holes H1 and H2 may also be removed. Then, the first to third recesses OP1, OP2 and OP3 may be filled by depositing a conductive material such as polycrystalline silicon. A planarization process such as CMP may be performed so that the conductive material portion located on the first surface 110a of the first substrate 110 is removed to expose the protective layer 130. Through this process, a vertical transfer gate (TG), a buried gate electrode (GE), and a buried interconnect (BI) may be formed. In this manner, the vertical transfer gate (TG), the buried gate electrode (GE), and the buried interconnect (BI) may be provided as structures buried in the first substrate 110. The upper surfaces of the electrode pad (BP) of the vertical transfer gate (TG), the buried gate electrode (GE), and the buried interconnect (BI) may be provided at a level almost identical to or slightly lower than the upper surface of the protective layer 130.

Additionally, referring to FIG. 9E, the protective layer 130 may be removed in the preceding planarization process so that the first surface 110a of the first substrate 110 is exposed. In some embodiments, the results illustrated in FIG. 9e may be obtained by performing the processes described above in FIG. 9A without providing the protective layer 110.

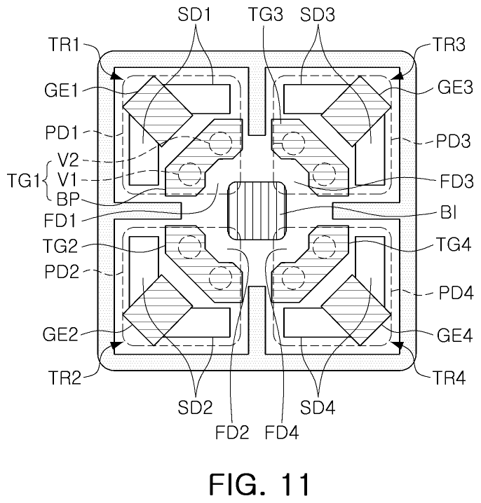

FIG. 11 is a plan view illustrating a pixel array (4×4) of an image sensor according to an example embodiment.

Referring to FIG. 11, the image sensor 10B according to the embodiment may include a pixel divided into four sub-pixels. The four sub-pixels are arranged in a matrix form of two rows and two columns, and may include each of first to fourth photoelectric conversion regions PD1, PD2, PD3 and PD4 provided in a semiconductor substrate (for example, a first substrate). The pixel separation pattern 150 surrounding the pixel may have extensions that separate the four sub-pixels.

The first to fourth sub-pixels may each include a first active region and a second active region ACT2 defined by a device isolation pattern 112 in the semiconductor substrate 110. The first active regions may be provided adjacent to each corner of the pixel, and the second active region may be provided adjacent to the center of the pixel. Logic transistors TR1, TR2, TR3 and TR4 for a pixel circuit may be formed in the first active regions. The logic transistors TR1, TR2, TR3 and TR4 may include first to fourth buried gate electrodes GE1, GE2, GE3 and GE4, respectively, and source/drain regions SD1, SD2, SD3 and SD4 located on both sides thereof. For example, the logic transistors TR1, TR2, TR3 and TR4 may include a source follower gate (SF), a selection gate (SEL), and a reset gate (RG). The first to fourth buried gate electrodes GE1, GE2, GE3 and GE4 provided in the embodiment may have a structure buried in a semiconductor substrate (for example, the first substrate) similar to the buried gate electrode (GE) described in FIG. 6A.

On the second active regions, first to fourth floating diffusion regions FD1, FD2, FD3 and FD4, respectively, and first to fourth vertical transfer gates TG1, TG2, TG3 and TG4 adjacent thereto may be provided.

The first to fourth vertical transfer gates TG1, TG2, TG3 and TG4 provided in the embodiment may have a structure embedded in a semiconductor substrate similar to the vertical transfer gate (TG) described in FIGS. 6A and 6B. The first to fourth vertical transfer gates TG1, TG2, TG3 and TG4 may include first to second vertical electrodes V1 and V2 connected to the first to fourth photoelectric conversion regions PD1, PD2, PD3 and PD4, respectively, and electrode pads (BP) connected to the first and second vertical electrodes V1 and V2 and embedded in the semiconductor substrate. The electrode pads (BP) may have other shapes optimized for corner regions adjacent to the center rather than being rectangular in a planar view.

As illustrated in FIG. 11, the first to fourth floating diffusion regions FD1, FD2, FD3 and FD4 may be arranged adjacent to the center of the pixel with the device isolation patterns 112 interposed therebetween. In the embodiment, the first to fourth floating diffusion regions FD1, FD2, FD3 and FD4 may be connected by a buried interconnection (BI). The buried interconnection (BI) provided in the embodiment may have a buried structure similar to the buried interconnection (BI) illustrated in FIG. 6B. The buried interconnection (BI) may be provided to overlap with the portions adjacent to the center of the first to fourth floating diffusion regions FD1, FD2, FD3 and FD4 in a planar view.

In this manner, in various pixel structures, the first to fourth vertical transfer gates TG1, TG2, TG3 and TG4, the first to fourth buried gate electrodes GE1, GE2, GE3 and GE4, and the buried interconnection (BI) may be formed into a buried structure through the same process. As a result, the upper surfaces of the electrode pads (BP) of the respective first to fourth vertical transfer gates TG1, TG2, TG3 and TG4, the first to fourth buried gate electrodes GE1, GE2, GE3 and GE4, and the buried interconnect (BI) may be provided at a level almost identical to or slightly lower than the upper surface of the semiconductor substrate.

As set forth above, according to the example embodiments described above, there is provided a structure in which electrode pads commonly connecting a plurality of vertical electrodes of a vertical transfer gate (VTG) are embedded in a semiconductor substrate, thereby improving electrical characteristics. In some embodiments, a structure in which the interconnection and/or gates of other transistors constituting a pixel circuit are easily buried through the same process may be provided.

While example embodiments have been illustrated and described above, it will be apparent to those skilled in the art that modifications and variations could be made without departing from the scope of the disclosure as defined by the appended claims.

What is claimed is:

1. An image sensor comprising:
a semiconductor substrate having a first surface and a second surface;
a photoelectric conversion region in the semiconductor substrate;
a device isolation pattern provided on the first surface of the semiconductor substrate and defining an active region;
a floating diffusion region provided adjacent to the first surface of the semiconductor substrate; and
a vertical transfer gate extending from the first surface of the semiconductor substrate towards the second surface of the semiconductor substrate and provided adjacent to the floating diffusion region,
wherein the vertical transfer gate comprises:
a first vertical electrode and a second vertical electrode, each of the first vertical electrode and the second vertical electrode extending in a vertical direction into the semiconductor substrate; and
an electrode pad embedded in the semiconductor substrate and connecting the first vertical electrode and the second vertical electrode.

2. The image sensor of claim 1, further comprising:
an interconnection structure on the first surface of the semiconductor substrate,
wherein the interconnection structure comprises a contact via connected to the electrode pad.

3. The image sensor of claim 1, wherein the device isolation pattern has a portion provided around the vertical transfer gate, and a width of the electrode pad is defined by the device isolation pattern.

4. The image sensor of claim 1, wherein the first and second vertical electrodes and the electrode pad have an integrated structure including a same material.

5. The image sensor of claim 1, wherein an upper surface of the electrode pad is at a same level as or is at a level lower than the first surface of the semiconductor substrate.

6. The image sensor of claim 1, further comprising a buried gate electrode embedded in the active region from the first surface of the semiconductor substrate.

7. The image sensor of claim 6, wherein the buried gate electrode and the electrode pad have a same depth from the first surface of the semiconductor substrate.

8. The image sensor of claim 6, wherein the buried gate electrode comprises a same material as a material of the vertical transfer gate.

9. The image sensor of claim 8, wherein the buried gate electrode and the vertical transfer gate comprises polysilicon.

10. The image sensor of claim 6, further comprising a pair of source/drain regions in the active region between sides of the buried gate electrode and the device isolation pattern.

11. The image sensor of claim 6, further comprising an insulating layer provided on the first surface of the semiconductor substrate in an area excluding the vertical transfer gate and the buried gate electrode.

12. An image sensor comprising:
a semiconductor substrate having a first surface and a second surface;
a first photoelectric conversion region and a second photoelectric conversion region provided adjacent to each other in the semiconductor substrate;
a first floating diffusion region and a second floating diffusion region provided adjacent to the first surface of the semiconductor substrate and overlapping the first and second photoelectric conversion regions in a vertical direction that is perpendicular to the first surface, respectively; and
a first vertical transfer gate and a second vertical transfer gate extending from the first surface of the semiconductor substrate toward the second surface of the semiconductor substrate, the first vertical transfer gate and the second vertical transfer gate and provided adjacent to the first and second floating diffusion regions, respectively,
wherein the first vertical transfer gate comprises: a plurality of first vertical electrodes each extending in the vertical direction in the semiconductor substrate, and
a first electrode pad embedded in the semiconductor substrate and connecting the plurality of first vertical electrodes, and
wherein the second vertical transfer gate comprises:
a plurality of second vertical electrodes each extending in the vertical direction in the semiconductor substrate, and
a second electrode pad embedded in the semiconductor substrate and connecting the plurality of second vertical electrodes.

13. The image sensor of claim 12, further comprising:
a buried interconnection portion embedded in the semiconductor substrate and connecting the first and second floating diffusion regions to each other.

14. The image sensor of claim 13, wherein the buried interconnection portion and the first and second electrode pads have a same depth from the first surface of the semiconductor substrate.

15. The image sensor of claim 13, wherein each of the first and second vertical transfer gates comprises a gate electrode portion and a gate insulating layer between the gate electrode portion and the semiconductor substrate, and
the buried interconnection portion comprises a material same as a material of the gate electrode portion.

16. The image sensor of claim 13, further comprising:
a device isolation pattern configured to separate the first and second floating diffusion regions,
wherein the buried interconnection portion is provided on the device isolation pattern.

17. The image sensor of claim 13, further comprising:
first and second buried gate electrodes embedded in the semiconductor substrate.

18. The image sensor of claim 17, wherein the first and second buried gate electrodes and the first and second electrode pads have a same depth from the first surface of the semiconductor substrate.

19. The image sensor of claim 17, wherein the first and second buried gate electrodes comprise a same material as a material of the first and second vertical transfer gates.

20. An image sensor comprising:
a semiconductor substrate having a first surface and a second surface;
a photoelectric conversion region in the semiconductor substrate;
a device isolation pattern provided on the first surface of the semiconductor substrate and defining an active region;
a floating diffusion region provided adjacent to the first surface of the semiconductor substrate;
a vertical transfer gate extending from the first surface of the semiconductor substrate towards the second surface of the semiconductor substrate and provided adjacent to the floating diffusion region; and
a buried gate electrode embedded in the active region from the first surface of the semiconductor substrate to a first depth,
wherein the vertical transfer gate comprises:
a first vertical electrode and a second vertical electrode extending to a second depth greater than the first depth, in a vertical direction in the semiconductor substrate, and
an electrode pad embedded in the semiconductor substrate from the first surface of the semiconductor substrate to the second depth and connecting the first and second vertical electrodes.
